(19) United States
(12) Patent Application Publication
(10) Pub. No.: US 2026/0181940 A1
(43) Pub. Date: Jun. 25, 2026

(54) SEMICONDUCTOR STRUCTURE AND FORMING METHOD THEREOF

(71) Applicant: Taiwan Semiconductor Manufacturing Company, Ltd., Hsinchu (TW)

(72) Inventors: Ming-Heng Tsai, Taipei City (TW); Ta-Chun LIN, Hsinchu (TW)

(73) Assignee: Taiwan Semiconductor Manufacturing Company, Ltd., Hsinchu (TW)

(21) Appl. No.: 19/001,352

(22) Filed: Dec. 24, 2024

(51) Int. Cl. H10D 30/00; H10D 30/01

(52) U.S. Cl. CPC H10D 30/502; H10D 30/0191

(57) ABSTRACT

A semiconductor structure includes a substrate, a channel structure, a source/drain feature (S/D feature), and a source/drain contact (S/D contact) is provided. The substrate includes a channel region and a source/drain region. The channel structure is disposed on the substrate corresponding to the channel region. The source/drain feature is disposed on the structure corresponding to the source/drain region. The source/drain contact is at least embedded in the source/drain feature.

### BACKGROUND

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. For these advances, similar developments in device fabrication are needed for improving performance (e.g., reducing resistance, reducing leakage current, and/or improving heat dissipation).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1E illustrate a portion of a manufacturing method of a semiconductor structure of an embodiment of the disclosure.

FIG. 2 illustrates a portion of a semiconductor structure of an embodiment of the disclosure.

FIG. 3 illustrates a portion of a semiconductor structure of an embodiment of the disclosure.

FIG. 4 illustrates a portion of a semiconductor structure of an embodiment of the disclosure.

FIG. 5 illustrates a portion of a semiconductor structure of an embodiment of the disclosure.

FIG. 6 illustrates a portion of a semiconductor structure of an embodiment of the disclosure.

FIG. 7 illustrates a portion of a semiconductor structure of an embodiment of the disclosure.

FIG. 8 illustrates a portion of flow for a manufacturing method of a semiconductor structure of an embodiment of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

A nanostructure transistor, for example, gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in an embodiment, a sacrificial layer is formed over a substrate (e.g., a wafer) and patterned using a photolithography process. Spacers are formed alongside the patterned sacrificial layer using a self-aligned process. The sacrificial layer is then removed, and the remaining spacers may then be used to pattern the GAA device.

The disclosure may be related to semiconductor devices and methods of forming the same. More particularly, the present disclosure is related to a nanostructure device integrated with a FinFET device. A nanostructure device, for example, gate-all-around (GAA), includes a device that has its gate structure, or portions thereof, formed on four-sides of a channel region (e.g., surrounding a portion of a channel region). The channel region of a nanostructure device may include nanostructure channels, for example, nanowire channels, bar-shaped channels, and/or other suitable channel configurations. In some embodiments, the channel region of a GAA device may have multiple horizontal nanostructures (such as horizontal nanowires or horizontal bars) vertically spaced, making the GAA device a stacked horizontal GAA (S-HGAA) device. Further, the GAA devices may have one or more nanostructures channel regions (e.g. nanowires, nanosheets) associated with a single, contiguous gate structure, or multiple gate structures. One of ordinary skill may recognize other examples of semiconductor devices that may benefit from aspects of the present disclosure.

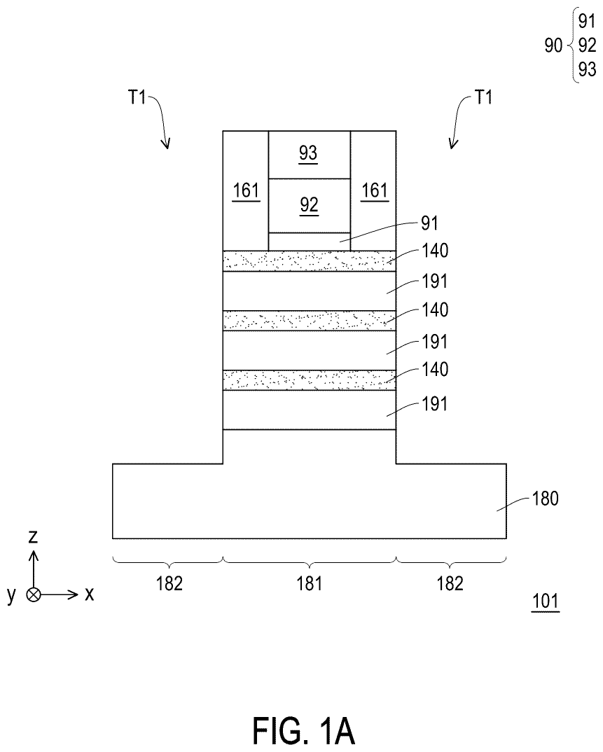

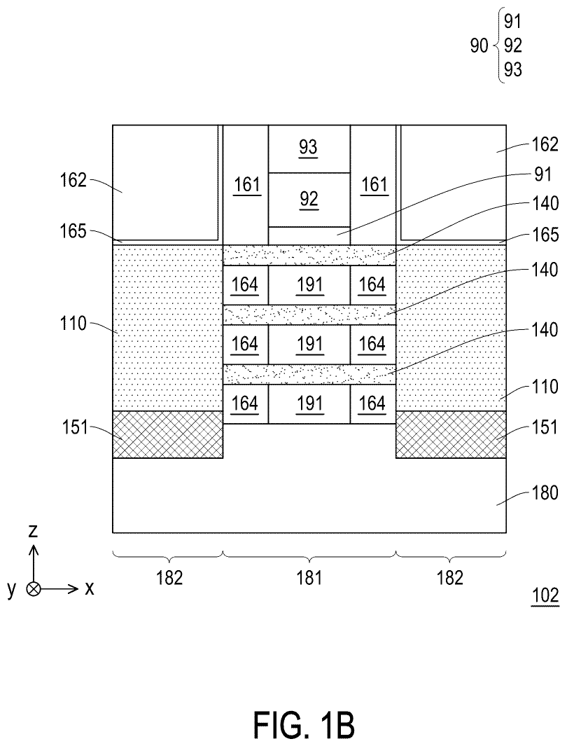

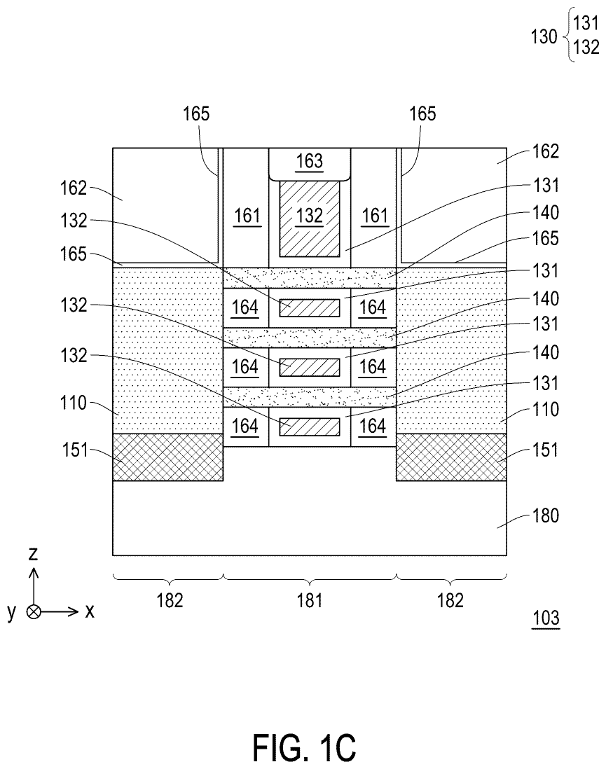

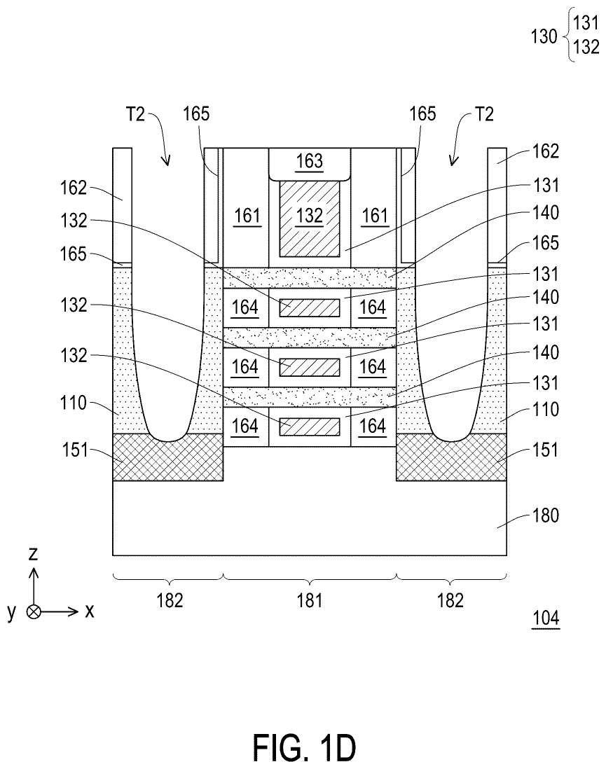

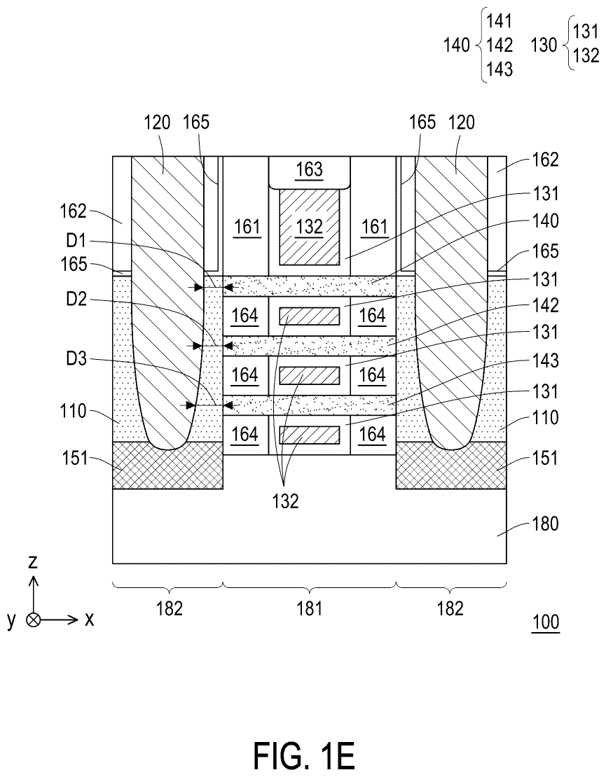

FIGS. 1A to 1E illustrate a portion of a manufacturing method of a semiconductor structure of an embodiment of the disclosure.

Referring to FIG. 1A, a structure 101 including stacked semiconductor layers is provided. In an embodiment, the structure 101 is formed by common semiconductor manufacturing processes.

For example, a substrate could be provided. In an embodiment, the substrate is a semiconductor substrate. In an embodiment, the substrate includes a single crystalline semiconductor layer on at least the surface of the substrate. In an embodiment, a material of the substrate includes silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and/or indium phosphide (InP), but the disclosure is not limited thereto. For example, the substrate is a Si substrate. In an embodiment, the substrate is a silicon-on-insulator (SOI) substrate, which includes an insulating layer disposed between two silicon layers. In an embodiment, the aforementioned insulating layer includes an oxide layer. An etching process, a doping process, and/or a deposition process may be performed to the substrate for forming one or more corresponding recesses (e.g., a recess for a shallow hole/trench isolation structure), doped regions (e.g., an n-type doped region, and/or a p-type doped region), and/or layers (e.g., a barrier layer, an insulating layer, or/and an etching stop layer). Structurally, the aforementioned recesses, doped regions, and/or layers may be considered as a portion of the substrate, so that the substrate having the above-mentioned recesses, doped regions and/or layers may still be simply referred as a substrate 180.

Then, a multilayer structure could be formed over the substrate. The multilayer structure includes alternatingly arranged first semiconductor layers and second semiconductor layers. In an embodiment, the first and second semiconductor layers are formed by a deposition process, such as epitaxy. For example, epitaxial growth of the layers of the alternatingly arranged layers is performed by a molecular beam epitaxy (MBE) process, a metalorganic chemical vapor deposition (MOCVD) process, and/or other suitable epitaxial growth processes. The first semiconductor layers and the second semiconductor layers having different etch selectivity and/or oxidation rates. For example, the first semiconductor layers substantially predominantly include Si, and the second semiconductor layers substantially predominantly include SiGe.

Then, fins could be formed by a suitable process, such as double-patterning or multi-patterning processes. For example, a sacrificial layer could be formed over the substrate 180 and patterned by a photolithography process. Spacers could be formed alongside the patterned sacrificial layer using a self-aligned process. The sacrificial layer is then removed, and the remaining spacers are then used to pattern the fins by etching the multilayer structure (including the first and second semiconductor layers) and the substrate 180. As shown in FIG. 1A, one fin is illustrated for example; however, the number of the fins is not limited.

In an embodiment, an insulating material for forming a subsequent shallow trench isolation (STI) is formed over the substrate 180 and in holes/trenches, but the disclosure is not limited thereto. A planarization process (e.g., a chemical mechanical polishing (CMP) process) and/or an etch-back process could be performed for exposing the tops of the fins from the insulating material. A portion of the insulating material between adjacent fins could be removed. The remaining portion of the insulating material configures the STI.

Then, a sacrificial gate dielectric layer, a sacrificial gate electrode layer, and a mask layer could be formed by a suitable process (e.g., a deposition process) over the fins and the STI. The sacrificial gate dielectric layer may include one or more layers of dielectric material, such as SiO₂, SiN, a high-k dielectric material, and/or other suitable dielectric material. In an embodiment, the sacrificial gate electrode layer includes polycrystalline silicon (polysilicon). In an embodiment, the mask layer includes a multilayer structure.

Then, as shown in FIG. 1A, sacrificial gate stacks 90 are formed by one or more pattern and/or etch processes performed on the deposited sacrificial gate dielectric layer, sacrificial gate electrode layer, and mask structure. A pattern process may include a lithography process. An etch process may include a dry etch (e.g., RIE) process, a wet etching, other etching methods, and/or combinations thereof. Each sacrificial gate stack 90 includes the remained sacrificial gate dielectric layer 91 (e.g., a portion of the previous sacrificial gate dielectric layer), sacrificial gate electrode layer 92 (e.g., a portion of the previous sacrificial gate electrode layer), and mask structure 93 (e.g., a portion of the previous mask structure). As shown in FIG. 1A, one sacrificial gate stack 90 is illustrated for example; however, the number of the sacrificial gate stacks 90 is not limited.

Spacers 161 could be formed on sidewalls of the sacrificial gate stacks 90. For example, the spacers 161 are formed by first depositing a conformal dielectric layer that is subsequently etched back to form the spacers 161. A material of the spacers 161 may include silicon oxide, silicon nitride, silicon carbide, silicon oxynitride, SiCN, silicon oxycarbide, SiOCN, and/or combinations thereof. In an embodiment, the spacers 161 include multiple layers.

Exposed portions of the stacks of first and second semiconductor layers of the fins not covered by the sacrificial gate stacks 90 and the spacers 161 are selectively removed, e.g., by one or more suitable etching processes to form holes/trenches T1. Edge portions of the remained first semiconductor layers 140 (e.g., a portion of the previous first semiconductor layers) and the remained second semiconductor layers 191 (e.g., a portion of the previous second semiconductor layers) are exposed in the holes/trenches T1. In a subsequent structure, a portion of at least one of the first semiconductor layers 140 may be formed to a channel. Two holes/trenches T1 corresponding to one separated stacked structure for exposing the first semiconductor layers 140 (which will be formed to a channel in a subsequent process or structure) thereof may be referred as source/drain holes/trenches (S/D holes/trenches). The holes/trenches T1 may also expose portions of the substrate 180. As such, a structure the same or similar to the structure 101 as shown in FIG. 1A is substantially formed.

Then, the exposed edge portions of the second semiconductor layers 191 are removed, for example, by a selective etching process. For example, in an embodiment where the second semiconductor layers 191 comprise SiGe, and the first semiconductor layers 140 comprise Si, a selective wet etching reagent is configured to etch the second semiconductor layer 191 at a higher etching rate, and the selective wet etching reagent is configured to etch the first semiconductor layers 140 at a slower etching rate. As a result, the exposed edge portions of the second semiconductor layers 191 could be removed, whereas the first semiconductor layers 140 are substantially unchanged. Moreover, the remained second semiconductor layers 191 are referred to herein by the same reference numerals for simplicity.

A dielectric material could be deposited over and into the spaces created by the partial removal of the edge portions of the second semiconductor layers 191. The dielectric material filling in the spaces created by the partial removal of the edge portions of the second semiconductor layers 191 configures inner spacers 164. Examples of the dielectric material forming the inner spacers 164 include, but are not limited to, a low-k dielectric material, such as SiO₂, SiN, SiCN, SiOC, or SiOCN, or a high-k dielectric material, such as HfO₂, ZrOₓ, ZrAlOₓ, HfAlOₓ, HfSiOₓ, AlOₓ, or other suitable dielectric material. In an example process, the inner spacers 164 are formed by depositing a conformal layer of the dielectric material, using a conformal deposition process, such as ALD, followed by an anisotropic etching to remove portions of the conformal layer other than the inner spacers 164.

Referring to FIG. 1B, a dielectric layer 151 is formed in the holes/trenches T1 (as shown in FIG. 1A). The dielectric layer 151 may include a silicon nitride (SiN) layer, a silicon oxide (SiO) layer, a silicon oxynitride (SiON) layer, a silicon carbonitride (SiCN) layer, a silicon carbon oxynitride (SiCON), a silicon oxycarbide (SiOC) layer, a high-k material (e.g., hafnium oxide (HfO), zirconia oxide (ZrO), aluminum oxide (AlO), but the disclosure is not limited thereto) layer, a stack or combinations thereof. The dielectric constant of the dielectric layer 151 is greater than that of thermal silicon oxide; for more example, over 6; for further more example, 6˜10. The dielectric layer 151 may be deposited by a suitable deposition process (e.g., an atomic layer deposition (ALD) process, a plasma-enhanced ALD (PEALD) process, a plasma-enhanced chemical vapor deposition (PECVD) process, but the disclosure is not limited thereto).

In an embodiment, a topmost position (e.g., a top surface) of the dielectric layer 151 and a topmost position (e.g., a top surface) of the substrate 180 are substantially not leveled. For example, the topmost position of the dielectric layer 151 has a higher level than the topmost position of the substrate 180. The dielectric layer 151 may partially cover the bottommost inner spacer 164. As such, the possibility of leakage current may be reduced.

In an embodiment, the dielectric layer 151 is referred as a bottom dielectric (BDI) layer, but the disclosure is not limited thereto.

Continually referring to FIG. 1B, source/drain features (S/D features) 110 are further formed in the holes/trenches T1 (as shown in FIG. 1A), and in contact with the dielectric layer 151 and exposed edge portions of the first semiconductor layers 140. In an embodiment, the S/D features 110 may be epitaxially and selectively formed from surfaces of the holes/trenches T1. A suitable epitaxial process may include a vapor-phase epitaxy (VPE) process, an ultra-high vacuum CVD (UHV-CVD) process, a molecular beam epitaxy (MBE) process, and/or other suitable processes. An epitaxial growth process may use gaseous precursors, which interact with the composition of surfaces of the holes/trenches T1. In an embodiment, the S/D features 110 include one or more layers of Si, SiP, SiC and SiCP to configure an N-type semiconductor device. In an embodiment, the S/D features 110 comprise one or more layers of Si, SiGe, Ge to configure a P-type bottom semiconductor device.

In an embodiment, a contact etching stop layer (CESL) 165 is optionally formed over the S/D features 110. A material of the CESL 165 may include silicon nitride, silicon carbon nitride, silicon oxynitride, carbon nitride, silicon oxide, silicon carbon oxide, the like, or a combination thereof, but the disclosure is not limited thereto. The CESL 165 could be formed by CVD, PECVD, ALD, or any suitable deposition technique.

A dielectric layer 162 is formed over the S/D features 110, or further over the CESL 165 (if any). A material of the dielectric layer 162 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials, but the disclosure is not limited thereto. The ILD layer 72 is deposited by a PECVD process or other suitable deposition technique. In an embodiment, the dielectric layer 162 is referred as an interlayer dielectric (ILD) layer, but the disclosure is not limited thereto. As such, a structure the same or similar to the structure 102 as shown in FIG. 1B is substantially formed.

Then, a removal process is performed to remove the mask layer 93 and expose the sacrificial gate electrode layer 92. The removal process may optionally further remove portions of the spacers 161, the dielectric layer 162 and the CESL 165 (if any), for example, a polishing process is performed. Then, the exposed sacrificial gate electrode layer 92 and the sacrificial gate dielectric layer 91 are removed, e.g., by one or more suitable processes, such as dry etch, wet etch, or a combination thereof.

Subsequently, the second semiconductor layers 191 are removed by a selective etching process. As a result, the second semiconductor layers 191 could be removed, whereas the first semiconductor layers 140 are substantially unchanged. The removal of the second semiconductor layers 191 exposes the inner spacers 164 and the first semiconductor layers 140, and creates spaces between and around exposed portions of the first semiconductor layers 140 not covered by the inner spacers 164. The remained first semiconductor layers 140 could be referred as channel layers 140, and may have a formation of nanosheets correspondingly. Moreover, the remained first semiconductor layers 140 are referred to herein by the same reference numerals of the channel layers 140 for simplicity.

Then, a gate dielectric layer 131 is formed over and around each of the channel layers 140. In an embodiment, a material of the gate dielectric layer 131 is the same or similar to the material of the aforementioned sacrificial gate dielectric layer 91. In an embodiment, the gate dielectric layer 131 may include an interfacial layer and a high-k dielectric layer. High-K gate dielectrics, as used and described herein, include dielectric materials having a high dielectric constant, for example, greater than that of thermal silicon oxide (dielectric constant is about 3.9); for more example, over 12; for further more example, 25˜30. The interfacial layer may include a dielectric material such as silicon oxide, hafnium silicate, or silicon oxynitride. The interfacial layer may be deposited using chemical oxidation, thermal oxidation, atomic layer deposition (ALD), chemical vapor deposition (CVD), and/or other suitable method. The high-K dielectric layer may include a high-K dielectric layer such as hafnium oxide. Alternatively, the high-K dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K dielectric layer may be formed by ALD, physical vapor deposition (PVD), CVD, oxidation, and/or other suitable methods.

A gate electrode material is formed over and around the gate dielectric layers 131, and the channel layers 140. The gate electrode material surrounding each of the channel layers 140 configures the gate electrode 132. In an embodiment, the gate electrode material comprises multiple gate electrode layers. The gate electrode material may include a single layer or alternatively a multi-layer structure, such as various combinations of a metal layer with a selected work function to enhance the device performance (work function metal layer), a liner layer, a wetting layer, an adhesion layer, a metal alloy layer and/or a metal silicide layer. By way of example, a material of the gate electrode 132 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In an embodiment, the gate electrode material includes a P-type gate electrode layer, such as TiN, TaN, TiTaN, TiAlN, WCN, W, Ni, Co, or other suitable material, for configuring a P-type semiconductor device. In an embodiment, the gate electrode material includes an N-type gate electrode layer, such as TiAlC, TaAlC, TiSiAlC, TiC, TaSiAlC, or other suitable material, for configuring a N-type semiconductor device. Example processes for depositing the gate electrode material include, but are not limited to, PVD, CVD, ALD, electro-plating, or other suitable methods. In an embodiment, each of the gate electrode 132 includes a corresponding GAA structure. In an embodiment, the gates 132 are integral portions of a GAA structure which extends around each of the channels 140.

In an embodiment, at least a portion of the gate dielectric layer 131 and a portion of a gate electrode 132 is referred as a gate structure 130. That is, the gate structure 130 includes a gate dielectric layer 131 and a gate electrode 132 formed thereon. The gate structure 130 could be formed over and/or around the channel layers 140. For example, the gate structure 130 wraps around each of the channel layers 140 on the Y-Z plane.

In an embodiment, a dielectric layer 163 the same or similar to the dielectric layer 162 is deposited over the gate electrode 132. A planarization process could be further performed optionally. As such, a structure the same or similar to the structure 103 as shown in FIG. 1C is substantially formed.

In an embodiment, the dielectric layer 163 is suitable for protecting the gate structure 130 beneath thereto in one or more subsequent processes. In an embodiment, the dielectric layer 163 is referred as a capping layer.

In an embodiment, the dielectric layer 163 is suitable for reducing defects caused by misalignment during a subsequent lithography and etching process. In an embodiment, the dielectric layer 163 is referred as a self-aligned layer.

Referring to FIG. 1D, a suitable removal process could be performed for forming corresponding holes/trenches T2 penetrating through the dielectric layer 162, the CESL 165 (if any), and the S/D features 110, to expose the dielectric layer 151. The removal process may include one or more patterning processes (e.g., a lithography and etching process), including double-patterning or multi-patterning processes. In an embodiment, when the aforementioned removal process is performed, a portion of the dielectric layer 151 may be slightly removed. That is, the upper surface of the dielectric layer 151 may have corresponding downward recesses. As such, a structure the same or similar to the structure 104 as shown in FIG. 1D is substantially formed.

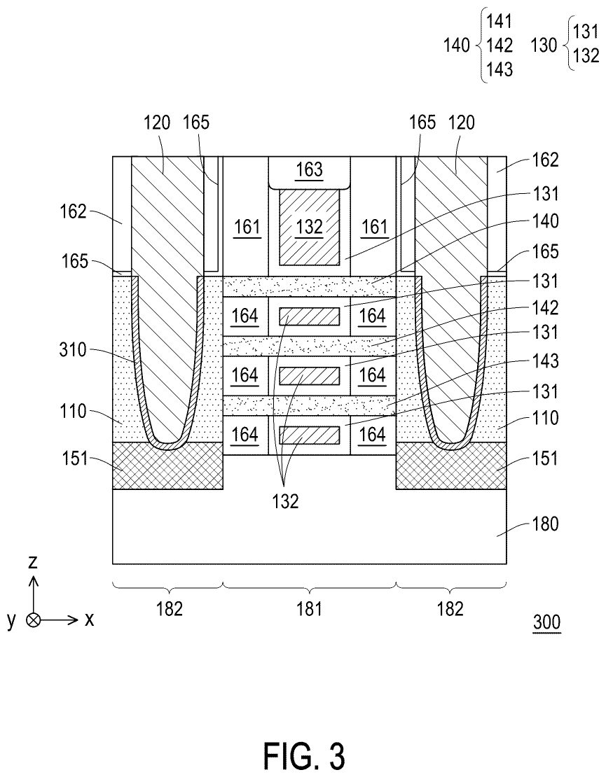

In an embodiment, one or more layers (e.g., a silicide layer the same or similar to the silicide layer 310 as shown in FIG. 3) is formed on the surface of the holes/trenches T2, to cover the dielectric layer 151, or further cover the S/D features 110, or more further cover the CESL 165 (if any) and the dielectric layer 162.

Referring to FIG. 1E, a conductive material could be applied filling at least the holes/trenches T2 and disposed on the exposed dielectric layer 151 by any suitable process, such as PVD, ECP, or CVD. Example materials of the aforementioned conductive material include, but are not limited to, Ru, Mo, Co, Ni, W, Ti, Ta, Cu, Al, a nitride of the above metallic element (e.g., titanium nitride (TiN), or tantalum nitride (TaN)), or a stack or combination thereof. As such, source/drain contacts 120 landing on the dielectric layer 151 are formed. In an embodiment, source/drain contacts 150 are referred as metal-to-device (MD) contacts, but the disclosure is not limited thereto. A structure the same or similar to the structure 100 as shown in FIG. 1E is substantially formed.

In an embodiment, a planarization process (e.g., a CMP process) may be performed to remove excessive conductive material.

One or more dielectric layers could be formed on the structure 100 as shown in FIG. 1E, for example, deposited over the source/drain contacts 120, the spacers 161, the dielectric layer 162, and/or the dielectric layer 163. One or more vias penetrating through the aforementioned one or more dielectric layers could be formed to electrically connect to (or further in contact with) the conductor of the structure 100. One or more vias electrically connect to (or further in contact with) the source/drain contacts 120 could be referred as via-to-device (VD) vias. One or more vias electrically connect to (or further in contact with) the gate electrode 132 could be referred as via-to-gate (VG) vias. In an embodiment, the formation of the VD, VG vias completes a front-end-of-line (FEOL) process. The FEOL process is followed by a middle-end-of-line (MEOL) process, and further a back-end-of-line (BEOL) process to provide routing for a semiconductor device.

FIG. 1E illustrates a portion of cross-section view of a semiconductor structure of an embodiment of the disclosure.

As shown in FIG. 1E, the semiconductor structure 100 includes a substrate 180, a channel (including at least one of the channel layers 140), a source/drain feature 110, and a source/drain contact 120. The substrate 180 has a channel region 181 and a source/drain region 182. The channel is disposed on the substrate 180 corresponding to the channel region 181. The source/drain feature 110 is disposed on the substrate 180 corresponding to the source/drain region 182.

In one or more embodiments, the source/drain contact 120 is disposed at least embedded in the source/drain feature 110. In one or more embodiments, the source/drain contact 120 is disposed further penetrating through the source/drain feature 110 and landing on a dielectric layer 151 below the source/drain feature 110.

In an embodiment, the dielectric layer 151 is disposed between the source/drain contact 120 and the substrate 180. In an embodiment, the source/drain contact 120 and the substrate 180 are not in physically contact with each other, at least through the dielectric layer 151 therebetween. The dielectric layer 151 could reduce the possibility of leakage current and/or metallic element diffusion. The possibility of leakage current may be reduced.

In an embodiment, the dielectric layer 151 laterally covers and/or is contact with the bottommost inner spacers 164. As such, the probability of contact between source/drain feature 110 and substrate 180 could be reduced. Therefore,

In an embodiment, the source/drain feature 110 is referred as an epitaxial source/drain feature, but the disclosure is not limited thereto.

In one or more embodiments, a thermal conductivity of the source/drain contact 120 is higher than a thermal conductivity of the source/drain feature; and/or an electrical conductivity of the source/drain contact 120 is higher than an electrical conductivity of the source/drain feature.

In an embodiment, the electrical conductivity of the source/drain contacts 120 is approximately 2 times or more, further approximately 5 times or more, further approximately 10 times or more that of the source/drain features 110. As such, if a device (e.g., a transistor) including the semiconductor structure 100 is enabled, an overall equivalent resistance of the current path may be reduced.

In an embodiment, the thermal conductivity of the source/drain contacts 120 is approximately 2 times or more, further approximately 5 times or more, further approximately 10 times or more, further approximately 50 times or more that of the source/drain features 110. As such, if a device (e.g., a transistor) including the semiconductor structure 100 is enabled, the heat dissipation path may be improved and/or the heat dissipation efficiency may be better.

In one or more embodiments, the channel region 181 includes a plurality of channel layers 140. In a direction perpendicular to the stacking direction of channel layers 140 (e.g., the x direction is perpendicular to the stacking of channel layers 140 in the z direction), at least one of the channel layers 140 is overlapped with the source/drain contact 120. As such, an equivalent current path and/or overall equivalent resistance between the source/drain contact 120 and the certain channel layer 140 overlapped therewith may be reduced, thereby the performance of the device (e.g., a transistor) including the semiconductor structure 100 may be improved and/or the operating power consumption of the device including the semiconductor structure 100 may be reduced.

In an embodiment, in a direction (e.g., the x direction) perpendicular to a stacking direction (e.g., the z direction) of the channel layers 140, more than two of the channel layers 140 are overlapped (e.g., completely overlapped) with the source/drain contact 120. For example, in the stacking direction, the bottommost position of the source/drain contact 120 is lower than at least two of the channel layers 140 (e.g., the topmost channel layer 141, and the channel layer 142 below and nearest thereto). In an embodiment, in the direction perpendicular to the stacking direction of channel layers 140, each of the channel layers 140 is overlapped (e.g., completely overlapped) with the source/drain contact 120.

In an embodiment, in a direction (e.g., the x direction) perpendicular to a stacking direction (e.g., the z direction) of the channel layers 140, the dielectric layer 151 is overlapped (e.g., partially overlapped) with the inner spacers 164. For example, in the stacking direction, the topmost position of the dielectric layer 151 is higher than the bottommost position of the bottommost inner spacers 164. In an embodiment, in the direction (e.g., the x direction) perpendicular to the stacking direction (e.g., the z direction) of the channel layers 140, the dielectric layer 151 is further overlapped (e.g., partially overlapped) with the gate electrode 132. For example, in the stacking direction, the topmost position of the dielectric layer 151 is higher than the bottommost position of the bottommost gate electrode 132.

In an embodiment, in the direction perpendicular to the stacking direction of channel layers 140, the distance between the source/drain contact 120 and each of the channel layers 140 substantially gradually increases toward the substrate 180. For example, in the direction perpendicular to the stacking direction of channel layers 140, the distance D2 between the source/drain contact 120 and the channel layer 142 is longer than the distance D1 between the source/drain contact 120 and the channel layer 141, and the distance D3 between the source/drain contact 120 and the channel layer 143 is longer than the distance D2 between the source/drain contact 120 and the channel layer 142.

It is worth noting that three channel layers (e.g., the channel layer 141, the channel layer 142, and the channel layer 143) are shown in the embodiment as shown in FIG. 1E, but the disclosure is not limited thereto. In various embodiments not shown, there may be two channel layers, four channel layers, five channel layers, or more channel layers. In an embodiment, the channel layers 140 may be sheet-like nanostructures (e.g., a nanosheet structure), but the disclosure is not limited thereto.

In an embodiment, the top surface of the S/D features 110 and the top surface of the gate electrode 132 are not coplanar. For example, the top surface of the gate electrode 132 is at a lower level (e.g., closer to the substrate 180) than the top surface of the S/D features 110. In a various embodiment not shown, the top surface of the S/D features 110 and the top surface of the gate electrode may be substantially coplanar, that is, the top surface of the gate electrode and the top surface of the S/D features 110 are substantially at a same level.

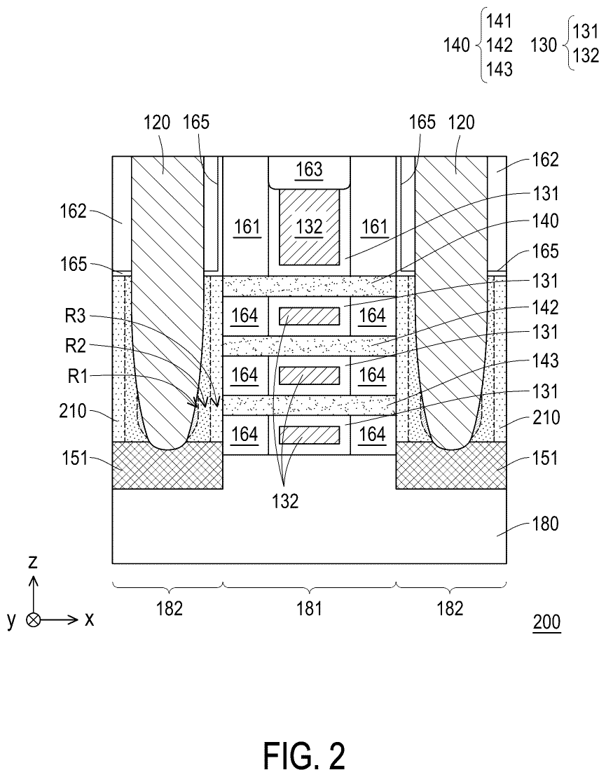

FIG. 2 illustrates a portion of cross-section view of a semiconductor structure of an embodiment of the disclosure. The semiconductor structure 200 as shown in FIG. 2 is similar to the semiconductor structure 100 as shown in FIG. 1E, in which similar elements are denoted by the same reference numerals and are assumed to have similar functions, materials or forming methods, so the descriptions thereof are omitted hereinafter.

As shown in FIG. 2, the semiconductor structure 200 includes a substrate 180, a channel (including at least one of the channel layers 140), a source/drain feature 210, and a source/drain contact 120. The source/drain feature 210 is disposed on the substrate 180 corresponding to the source/drain region 182.

In an embodiment, the source/drain feature 210 is referred as an epitaxial source/drain feature, but the disclosure is not limited thereto.

In one or more embodiments, the source/drain contact 120 is disposed penetrating through the source/drain feature 210 and landing on a dielectric layer 151 below the source/drain feature 210. In one or more embodiments, a thermal conductivity and/or an electrical conductivity of the source/drain contact 120 is higher than a thermal conductivity and/or an electrical conductivity of the source/drain feature 210.

In an embodiment, different regions of the source/drain features 210 have different dopant concentrations. For example, during a process (e.g., an epitaxial process) for forming S/D features 210, the concentration of dopant could be dynamically adjusted, and S/D features 210 with inconsistent dopant concentrations could be formed, but the disclosure is not limited thereto. Higher dopant concentration may reduce resistance and/or increase electrical conductivity.

In an embodiment, a topmost position (e.g., a top surface) of the dielectric layer 151 and a topmost position (e.g., a top surface) of the substrate 180 are substantially not leveled. For example, the topmost position of the dielectric layer 151 has a higher level than the topmost position of the substrate 180. The dielectric layer 151 may partially cover the bottommost inner spacer 164. As such, the possibility of leakage current may be reduced.

In an embodiment, in the direction perpendicular to the stacking direction of channel layers 140, the distance between the source/drain contact 120 and each of the channel layers 140 substantially gradually increases toward the substrate 180. For example, similar to the drawing as shown in FIG. 1E, in the direction (a direction parallel to the x direction) perpendicular to the stacking direction (e.g., the z direction) of channel layers 140, the distance D2 between the source/drain contact 120 and the channel layer 142 is longer than the distance D1 between the source/drain contact 120 and the channel layer 141, and the distance D3 between the source/drain contact 120 and the channel layer 143 is longer than the distance D2 between the source/drain contact 120 and the channel layer 142.

In an embodiment, in a direction perpendicular to the stacking direction of channel layers 140, the dopant concentration between the source/drain contact 120 and certain one channel layer (e.g., the channel layer 143) substantially gradually increases from the certain one channel layer (e.g., the channel layer 143) toward the source/drain contact 120. For example, if corresponding dopant concentrations are measured between the source/drain contact 120 and the channel layer 143, the dopant concentration of region R1 is higher than the dopant concentration of region R2, and the dopant concentration of region R2 is higher than the dopant concentration of region R3. The dopant concentration may be measured or observed, for example, by commonly used elemental analysis methods (such as energy-dispersive X-ray spectroscopy (EDX), the disclosure is not limited thereto).

In an embodiment, comparing with other channel layers (e.g., the channel layers 141, 142) different form the channel layer 143, there is a longer distance (e.g., the distance D3 as shown in FIG. 1E) between the source/drain contact 120 and the channel layer 143. As such, gradual concentration increase may reduce the equivalent resistance and/or improve the equivalent electrical conductivity between the source/drain contact 120 and the channel layer 143, thereby the performance of the device (e.g., a transistor) including the semiconductor structure 200 may be improved and/or the operating power consumption of the device including the semiconductor structure 200 may be reduced.

FIG. 3 illustrates a portion of cross-section view of a semiconductor structure of an embodiment of the disclosure. The semiconductor structure 300 as shown in FIG. 3 is similar to the semiconductor structure 100 as shown in FIG. 1E, in which similar elements are denoted by the same reference numerals and are assumed to have similar functions, materials or forming methods, so the descriptions thereof are omitted hereinafter.

As shown in FIG. 3, the semiconductor structure 300 includes a substrate 180, a channel (including at least one of the channel layers 140), a source/drain feature, a silicide layer 310, and a source/drain contact 120. The silicide layer 310 may be formed between the source/drain features 110 and the source/drain contacts 120, so as to reduce the source/drain contact 120 resistance. The silicide layer 310 may include a cobalt silicide (CoSi) layer, a nickel silicide (NiSi) layer, a titanium silicide (TiSi) layer, a stack or combinations thereof, but the disclosure is not limited thereto.

In an embodiment, the silicide layer 310 is formed by a selective deposition process. For example, after corresponding holes/trenches penetrating through the dielectric layer and the S/D features 110 are formed, a selective deposition process could be performed for depositing corresponding silicide material on the exposed inner surface of the S/D features 110. The silicide material may tend to be deposited on the exposed S/D features 110. It is relatively difficult for the silicone material to be disposed on the dielectric layer 151 and/or the dielectric layer 162. Then, a conductive material could be applied filling the holes/trenches partially covered by the silicide material, to contact the exposed dielectric layer 151. As such, the silicide layer 310 and source/drain contacts 120 landing on the dielectric layer 151 could be formed.

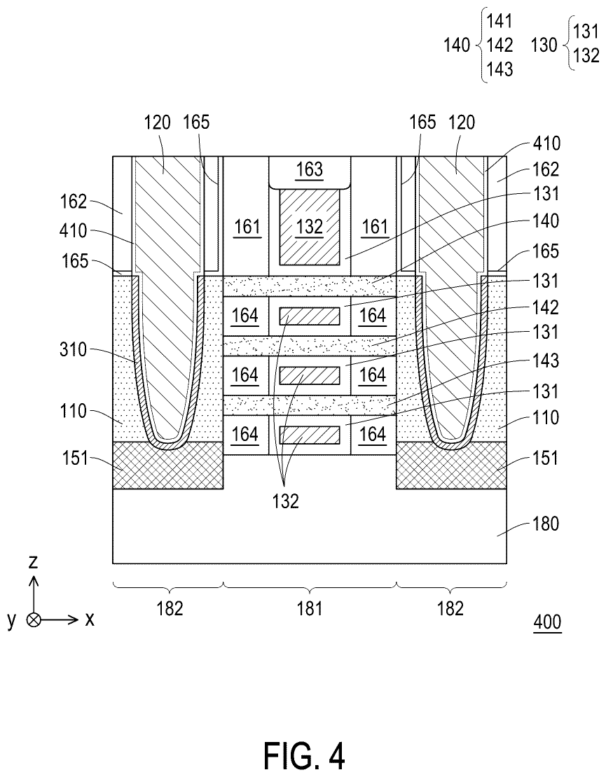

FIG. 4 illustrates a portion of cross-section view of a semiconductor structure of an embodiment of the disclosure. The semiconductor structure 400 as shown in FIG. 4 is similar to the semiconductor structure 300 as shown in FIG. 3, in which similar elements are denoted by the same reference numerals and are assumed to have similar functions, materials or forming methods, so the descriptions thereof are omitted hereinafter.

As shown in FIG. 4, the semiconductor structure 400 includes a substrate 180, a channel (including at least one of the channel layers 140), a source/drain feature, a silicide layer 310, a liner layer 410, and a source/drain contact 120.

The liner layer 410 may be formed between the silicide layer 310 and lower portions of the source/drain contacts 120, and between the dielectric layer 162 and upper portions of the source/drain contacts 120.

In an embodiment, the liner layer 410 could be referred as a conductive adhesion layer or a conductive glue layer. A metal material (e.g. a material for forming the source/drain contacts 120) may have good bonding with the conductive adhesion layer.

The liner layer 410 may be a single film layer or a combination or stack of multiple film layers. The liner layer 410 may include a titanium (Ti) layer, a titanium nitride (TiN) layer, a tantalum (Ta) layer, a tantalum nitride (TaN) layer, a stack or combinations thereof, but the disclosure is not limited thereto.

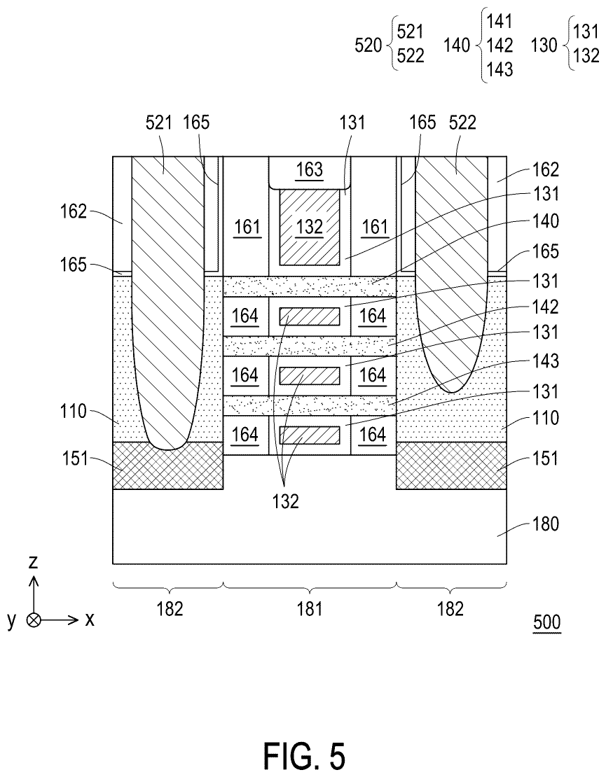

FIG. 5 illustrates a portion of cross-section view of a semiconductor structure of an embodiment of the disclosure. The semiconductor structure 500 as shown in FIG. 5 is similar to the semiconductor structure 100 as shown in FIG. 1E, in which similar elements are denoted by the same reference numerals and are assumed to have similar functions, materials or forming methods, so the descriptions thereof are omitted hereinafter.

As shown in FIG. 5, the semiconductor structure 500 includes a substrate 180, a channel (including at least one of the channel layers 140), source/drain features 110, and source/drain contacts 520. One of the source/drain contacts 520 is a source contact, and another one of the source/drain contacts 520 is a drain contact. The corresponding heights or depths of two source/drain contacts 520 are different.

In an embodiment, a deeper (closer to the substrate 180) or longer source/drain contact 521 may be more suitable as a source contact due to electron/hole mobility considerations. Typically, the mobility of electrons is higher than the mobility of holes. Therefore, a deeper contact might be more suitable for p-type.

In an embodiment, a deeper (closer to the substrate 180) or longer source/drain contact 521 may reduce a corresponding equivalent resistance, and/or a shallower (further away from substrate 180) or shorter source/drain contacts 522 may reduce a corresponding equivalent capacitance.

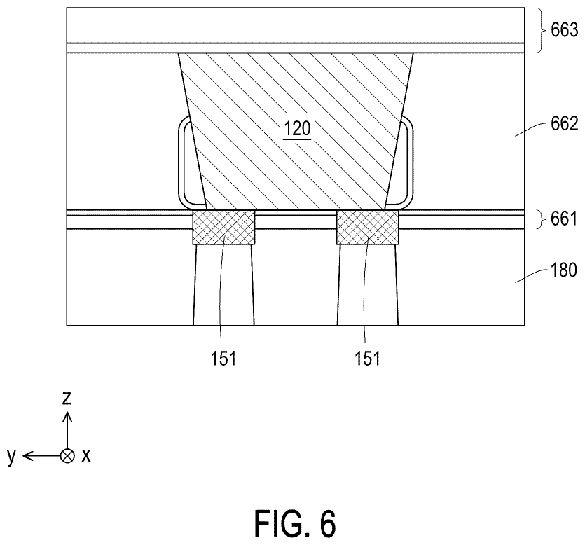

FIG. 6 illustrates a portion of cross-section view of a semiconductor structure of an embodiment of the disclosure. For example, FIG. 6 may illustrate a cross-sectional view corresponding to a certain source/drain contact of the aforementioned semiconductor structure in another cross-section (e.g., the cross-section perpendicular to the cross-section as shown in FIGS. 1E, 2, 3, 4 and/or 5).

In an embodiment, the source/drain contact 120 is further landing on a dielectric layer 661 away from and/or different form the dielectric layer 151. The dielectric layer 661 may be disposed between the substrate 180 and the source/drain contact 120. The dielectric layer 661 may be a single film layer or a combination or stack of multiple film layers. The dielectric layer 661 may be referred as a barrier layer, an etching stop layer, a flat layer, an anti-reflection layer, or a liner layer, a combination or stack of the aforementioned layers, but the disclosure is not limited thereto. The dielectric layer 661 may be a portion corresponding to a shallow trench isolation (STI) structure, but the disclosure is not limited thereto.

In an embodiment, the source/drain contact 120 is laterally covered by a dielectric layer 662. The dielectric layer 662 may be a single film layer or a combination or stack of multiple film layers forming by a front-end of line (FEOL) process.

In an embodiment, the source/drain contact 120 is covered by a dielectric layer 663. The dielectric layer 663 may be a single film layer or a combination or stack of multiple film layers forming by a front-end of line (FEOL) process, a middle-end of line (MEOL) process, or a back-end of line (BEOL) process.

In an embodiment not shown, a circuit may be disposed on the dielectric layer 662 and/or penetrate through the dielectric layer 663 for electrically connecting to the corresponding source/drain contact 120.

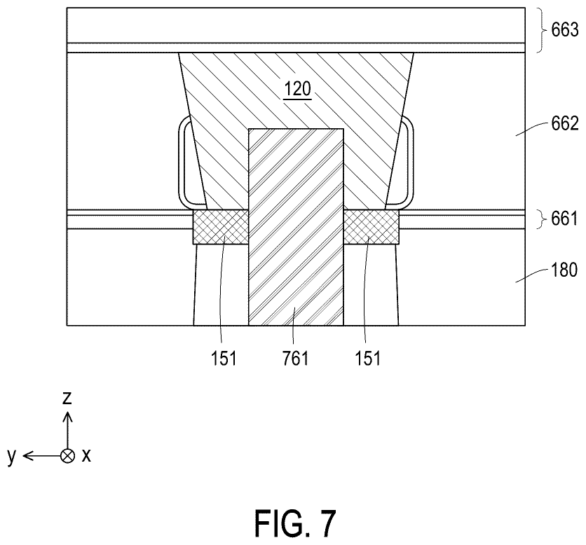

FIG. 7 illustrates a portion of cross-section view of a semiconductor structure of an embodiment of the disclosure. For example, FIG. 7 may illustrate a cross-sectional view corresponding to a certain source/drain contact of the aforementioned semiconductor structure in another cross-section (e.g., the cross-section perpendicular to the cross-section as shown in FIGS. 1E, 2, 3, 4 and/or 5).

In an embodiment, the source/drain contact 120 is further landing on a dielectric layer 761 away from and/or different form the dielectric layer 151. The dielectric layer 761 may be disposed between the substrate 180 and the source/drain contact 120. The dielectric layer 661 may be a single film layer or a combination or stack of multiple film layers. A portion of the dielectric layer 661 may protrude away from the substrate 180 to be embedded in the source/drain contact 120. The dielectric layer 761 may be an isolated dielectric layer within stacked nanosheets (NSs), and may be referred as a forksheet, but the disclosure is not limited thereto.

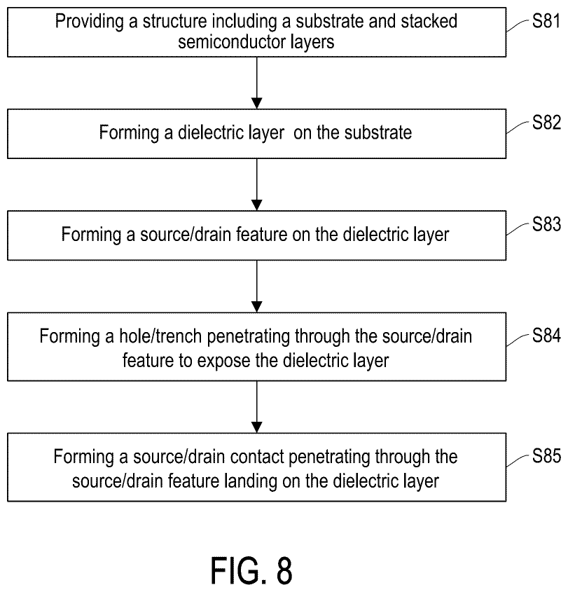

FIG. 8 illustrates a portion of flow for a manufacturing method of a semiconductor structure of an embodiment of the disclosure.

At act S81, a structure including a substrate and stacked semiconductor layers disposed thereon is provided. FIG. 1A or 1B illustrate cross-sectional views corresponding to various embodiments of act S81.

In an embodiment, the stacked semiconductor layers include a plurality of channel layers. In an embodiment, a gate structure wraps around each of the plurality of channel layers is formed.

At act S82, a bottom dielectric layer on the substrate is formed. FIG. 1B illustrates a cross-sectional view corresponding to various embodiments of act S82.

At act S83, a source/drain feature on the bottom dielectric layer is formed. FIG. 1C illustrates a cross-sectional view corresponding to various embodiments of act S83.

In an embodiment, an epitaxial growth process is performed for forming the source/drain feature. In an embodiment, the concentration of dopant could be adjusted for forming the source/drain feature having suitable dopant concentration.

In an embodiment, one or more dielectric layers disposed on the source/drain feature and/or the gate structure are formed.

At act S84, a hole/trench penetrating through the source/drain feature to expose the dielectric layer is formed. FIG. 1D illustrates a cross-sectional view corresponding to various embodiments of act S84.

In an embodiment, a silicide layer is formed on an exposed surface of the source/drain feature.

In an embodiment, the hole/trench further penetrating through the one or more dielectric layers disposed on the source/drain feature. In an embodiment, the silicide layer covers the surface of the hole/trench.

At act S85, a source/drain contact penetrating through the source/drain feature landing on the bottom dielectric layer is formed. FIGS. 1E, 2, 3, 4 and/or 5 illustrate cross-sectional views corresponding to various embodiments of act S85.

In accordance with some embodiments of the present disclosure, a semiconductor structure includes a substrate, a channel structure, a bottom dielectric layer, a source/drain feature, and a source/drain contact. The substrate has a channel region and a source/drain region. The channel structure is disposed on the substrate corresponding to the channel region. The bottom dielectric layer is disposed on the substrate at least corresponding to the source/drain region. The source/drain feature is disposed on the bottom dielectric layer corresponding to the source/drain region. The source/drain contact is disposed penetrating through the source/drain feature and landing on the bottom dielectric layer. In an embodiment, the source/drain feature is an epitaxial source/drain feature with inconsistent dopant concentration. In an embodiment, the dopant concentration substantially gradually increases from the channel structure to the source/drain contact. In an embodiment, a portion of the source/drain contact has a curved sidewall laterally corresponding to the source/drain feature and/or the channel structure. In an embodiment, the semiconductor structure further includes a gate structure, wherein the channel structure includes a plurality of channel layers, and the gate structure wraps around each of the plurality of channel layers. In an embodiment, the semiconductor structure further includes a silicide layer; the silicide layer is disposed between the source/drain feature and the source/drain contact, wherein the source/drain contact physically contacts with the bottom dielectric layer. In an embodiment, the semiconductor structure further includes a first dielectric layer; the first dielectric layer is disposed on the source/drain feature, wherein the source/drain contact further penetrates through the first dielectric layer. In an embodiment, the semiconductor structure further includes a gate structure and a second dielectric layer; the gate structure is disposed corresponding to the channel structure; the second dielectric layer is disposed on the gate structure and/or the channel structure, wherein a material of the first dielectric layer is different form a material of the second dielectric layer. In an embodiment, a thermal conductivity of the source/drain contact is higher than a thermal conductivity of the source/drain feature. In an embodiment, an electrical conductivity of the source/drain contact is higher than an electrical conductivity of the source/drain feature. In an embodiment, the semiconductor structure further includes a silicide layer disposed between the source/drain feature and the source/drain contact.

In accordance with some embodiments of the present disclosure, a semiconductor structure includes a substrate, a channel structure, a source/drain feature, and a source/drain contact. The substrate has a channel region and a source/drain region. The channel structure is disposed on the substrate corresponding to the channel region. The source/drain feature is disposed on the structure corresponding to the source/drain region. The source/drain contact is at least embedded in the source/drain feature, wherein: the channel structure includes a plurality of channel layers; and in a direction perpendicular to a stacking direction of the plurality of channel layers, at least one of the plurality of channel layers is overlapped with the source/drain contact. In an embodiment, in the direction perpendicular to the stacking direction of the plurality of channel layers, more than two of the plurality of channel layers are overlapped with the source/drain contact. In an embodiment, in the direction perpendicular to the stacking direction of the plurality of channel layers, each of the plurality of channel layers is overlapped with the source/drain contact. In an embodiment, in the direction perpendicular to the stacking direction of the plurality of channel layers, two distances between the source/drain contact and at least two of the plurality of channel layers are different. In an embodiment, in the direction perpendicular to the stacking direction of the plurality of channel layers, distances between the source/drain contact and each of the plurality of channel layers gradually increases toward the substrate. In an embodiment, the semiconductor structure further includes a dielectric layer; the dielectric layer is disposed between the substrate and the source/drain contact, wherein the source/drain contact physically contacts with the dielectric layer. In an embodiment, the semiconductor structure further includes a dielectric layer; the dielectric layer is disposed between the substrate and the source/drain contact, wherein a portion of the dielectric layer protrudes away from the substrate to be embedded in the source/drain contact. In an embodiment, the source/drain contact comprises a first source/drain contact and a second source/drain contact, and wherein the first source/drain is longer than the second source/drain. In an embodiment, the source/drain contact comprises a first source/drain contact and a second source/drain contact, and wherein: the first source/drain is embedded in and further penetrates through the source/drain feature; and the first source/drain is embedded in the source/drain feature.

In accordance with some embodiments of the present disclosure, a method for forming a semiconductor structure includes: providing a structure including a substrate and stacked semiconductor layers, wherein the substrate has a channel region and a source/drain region, wherein the stacked semiconductor layers are disposed on the substrate corresponding to the channel region; forming a dielectric layer on the substrate; forming a source/drain feature on the dielectric layer at least corresponding to the source/drain region; and forming a source/drain contact penetrating through the source/drain feature and landing on the dielectric layer. In an embodiment, the method further includes: forming a hole/trench penetrating through the source/drain feature to expose the dielectric layer; and filling the holes/trenches with a conductive material for forming the source/drain contact. In an embodiment, an upper surface of the dielectric layer has downward recesses after the hole/trench is formed.

In accordance with some embodiments of the present disclosure, a semiconductor structure includes a substrate, a channel structure, a source/drain feature, and a source/drain contact. The substrate has a channel region and a source/drain region. The channel structure is disposed on the substrate corresponding to the channel region. The source/drain feature is disposed on the structure corresponding to the source/drain region. The source/drain contact is at least embedded in the source/drain feature. A thermal conductivity of the source/drain contact is higher than a thermal conductivity of the source/drain feature; or an electrical conductivity of the source/drain contact is higher than an electrical conductivity of the source/drain feature. In an embodiment, the thermal conductivity of the source/drain contact is approximately 2 times or more than the thermal conductivity of the source/drain feature. In an embodiment, the electrical conductivity of the source/drain contact is approximately 2 times or more than the electrical conductivity of the source/drain feature. In an embodiment, a material of the source/drain contact includes metal; and/or the source/drain feature includes an epitaxial source/drain feature. In an embodiment, the source/drain contact includes a first source/drain contact and a second source/drain contact, and wherein the first source/drain is longer than the second source/drain. In an embodiment, the source/drain contact includes a first source/drain contact and a second source/drain contact, and wherein: the first source/drain is embedded in and further penetrates through the source/drain feature; and the first source/drain is embedded in the source/drain feature. In an embodiment, the semiconductor structure further includes a silicide layer, the silicide layer is disposed between the source/drain feature and the source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate, having a channel region and a source/drain region;
a channel structure, disposed on the substrate corresponding to the channel region;
a bottom dielectric layer, disposed on the substrate at least corresponding to the source/drain region;
a source/drain feature, disposed on the bottom dielectric layer corresponding to the source/drain region; and
a source/drain contact, disposed penetrating through the source/drain feature and landing on the bottom dielectric layer.

2. The semiconductor structure of claim 1, wherein the source/drain feature is an epitaxial source/drain feature with inconsistent dopant concentration.

3. The semiconductor structure of claim 2, wherein the dopant concentration substantially gradually increases from the channel structure to the source/drain contact.

4. The semiconductor structure of claim 1, wherein a portion of the source/drain contact has a curved sidewall laterally corresponding to the source/drain feature and/or the channel structure.

5. The semiconductor structure of claim 1, further comprising:
a gate structure, wherein the channel structure comprises a plurality of channel layers, and the gate structure wraps around each of the plurality of channel layers.

6. The semiconductor structure of claim 1, further comprising:
a first dielectric layer, disposed on the source/drain feature, wherein the source/drain contact further penetrates through the first dielectric layer.

7. The semiconductor structure of claim 6, further comprising:
a gate structure, disposed corresponding to the channel structure;
a second dielectric layer, disposed on the gate structure and/or the channel structure, wherein a material of the first dielectric layer is different form a material of the second dielectric layer.

8. The semiconductor structure of claim 1, wherein:
a thermal conductivity of the source/drain contact is higher than a thermal conductivity of the source/drain feature; or
an electrical conductivity of the source/drain contact is higher than an electrical conductivity of the source/drain feature.

9. The semiconductor structure of claim 1, further comprising:
a silicide layer, disposed between the source/drain feature and the source/drain contact.

10. A semiconductor structure, comprising:
a substrate, having a channel region and a source/drain region;
a channel structure, disposed on the substrate corresponding to the channel region;
at least one source/drain feature, disposed on the structure corresponding to the source/drain region; and
at least one source/drain contact, at least embedded in the source/drain feature, wherein:
the channel structure comprises a plurality of channel layers; and
in a direction perpendicular to a stacking direction of the plurality of channel layers, more than two of the plurality of channel layers are overlapped with the source/drain contact.

11. The semiconductor structure of claim 10, wherein in the direction perpendicular to the stacking direction of the plurality of channel layers, each of the plurality of channel layers is overlapped with the source/drain contact.

12. The semiconductor structure of claim 10, wherein in the direction perpendicular to the stacking direction of the plurality of channel layers, two distances between the source/drain contact and at least two of the plurality of channel layers are different.

13. The semiconductor structure of claim 10, wherein in the direction perpendicular to the stacking direction of the plurality of channel layers, distances between the source/drain contact and each of the plurality of channel layers gradually increases toward the substrate.

14. The semiconductor structure of claim 10, further comprising:
a dielectric layer, disposed between the substrate and the source/drain contact, wherein the source/drain contact physically contacts with the dielectric layer.

15. The semiconductor structure of claim 10, further comprising:
a dielectric layer, disposed between the substrate and the source/drain contact, wherein a portion of the dielectric layer protrudes away from the substrate to be embedded in the source/drain contact.

16. The semiconductor structure of claim 10, wherein the source/drain contact comprises a first source/drain contact and a second source/drain contact, and wherein the first source/drain is longer than the second source/drain.

17. The semiconductor structure of claim 16, wherein the source/drain contact comprises a first source/drain contact and a second source/drain contact, and wherein:
the first source/drain is embedded in and further penetrates through the source/drain feature; and
the first source/drain is embedded in the source/drain feature.

18. A method for forming a semiconductor structure, comprising:
providing a structure including a substrate and stacked semiconductor layers, wherein the substrate has a channel region and a source/drain region, wherein the stacked semiconductor layers are disposed on the substrate corresponding to the channel region;
forming a dielectric layer on the substrate;
forming a source/drain feature on the dielectric layer at least corresponding to the source/drain region; and
forming a source/drain contact penetrating through the source/drain feature and landing on the dielectric layer.

19. The method of claim 18, further comprising:
forming a hole/trench penetrating through the source/drain feature to expose the dielectric layer; and
filling the holes/trenches with a conductive material for forming the source/drain contact.

20. The method of claim 19, wherein an upper surface of the dielectric layer has downward recesses after the hole/trench is formed.
